(19) United States
(12) Patent Application Publication
(10) Pub. No.: US 2009/0126634 A1
(43) Pub. Date: May 21, 2009

(54) PLASMA PROCESSING APPARATUS

(75) Inventor: Yohei YAMAZAWA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/271,467

(22) Filed: Nov. 14, 2008

Related U.S. Application Data
(60) Provisional application No. 61/024,360, filed on Jan. 29, 2008.

(30) Foreign Application Priority Data
Nov. 15, 2007 (JP) 2007-296498

(51) Int. Cl. C23C 16/513

(52) U.S. Cl. 118/723 R

(57) ABSTRACT

A plasma processing apparatus includes a processing chamber; a first electrode for mounting thereon a target substrate in the processing chamber; a second electrode which faces the first electrode obliquely or in parallel thereto to form a high frequency discharging capacitor; a processing gas supply unit for supplying a processing gas to a processing space in the processing chamber; a first high frequency power supply for applying a first high frequency power to at least one of the first and the second electrode to generate a plasma by injecting the processing gas into the processing space; and an electrode position varying mechanism for varying a position of the second electrode in a predetermined direction to vary a capacitance of the capacitor. The apparatus further includes a dielectric partition wall for separating the processing space from an electrode moving space surrounding the second electrode and the electrode position varying mechanism.

### FIELD OF THE INVENTION

The present invention relates to a technique for performing plasma processing on a substrate to be processed; and, more particularly, to a capacitively coupled plasma processing apparatus.

### BACKGROUND OF THE INVENTION

In a manufacturing process of a semiconductor device or an FPD (flat panel display), a plasma is often used in processes, e.g., etching, deposition, oxidation, sputtering and the like, in order to make a processing gas react efficiently at a relatively low temperature. Conventionally, a capacitively coupled plasma processing apparatus capable of generating a plasma of a large diameter is mainly used for a single-wafer plasma processing apparatus.

Generally, in the capacitively coupled plasma processing apparatus, an upper and a lower electrode are disposed in parallel with each other in a processing chamber as a vacuum chamber, and a substrate to be processed (e.g., a semiconductor wafer, a glass substrate or the like) is mounted on the lower electrode. By applying a high frequency power (an RF power) to both electrodes, electrons accelerated by an electric field induced by an RF current, secondary electrons emitted from the electrodes, or heated electrons collide with molecules of a processing gas to generate ions. Accordingly, a plasma of the processing gas is generated, and a required microprocessing, e.g., etching, is performed on a substrate surface by radicals or ions in the plasma.

Meanwhile, with increasing demands for miniaturization and high integration of devices in the semiconductor processing technique, a high efficiency, high density and low bias plasma processing is required in the capacitively coupled plasma processing apparatus. To do so, the high frequency power for plasma generation tends to be set as high as possible. Meanwhile, along with the tendency to increase the chip size and the diameter of the substrate, the plasma is required to be of a large diameter and, therefore, a chamber (processing vessel) is scaled up accordingly.

Here, the problem is that it is difficult to have a uniform plasma density in a processing space of the chamber (especially, in a radial direction). That is, when a discharging RF frequency increases, the profile of the plasma density becomes high at a central portion of the substrate and low at an edge portion thereof due to the wavelength effect causing formation of standing waves in the chamber and/or a skin effect making the high frequency current be concentrated in the central portion on the electrode surface. The non-uniformity of the plasma density on the substrate leads to a non-uniformity of the plasma processing. As a consequence, the production yield of the semiconductor devices decreases.

To that end, various electrode structures have been developed. For example, in a plasma processing apparatus described in Patent Document 1, uniformity in a plasma density distribution is improved by inserting a dielectric member in a main surface of an electrode facing a processing space so that an impedance to a high frequency power emitted from the main surface of the electrode to the processing space increases at a central portion of the electrode and decreases at an edge portion of the electrode.

[Patent Document 1] Japanese Patent Laid-open Publication No. 2004-363552

The technique for inserting a dielectric member in a main surface of an electrode is disadvantageous in that the impedance distribution on the main surface of the electrode is fixed by a profile and a material of the dielectric member. Accordingly, a process region where the uniformity of the plasma density distribution can be controlled is small. Further, it is not possible to flexibly cope with various processes or changes of processing conditions.

### SUMMARY OF THE INVENTION

In view of the above, the present invention provides a capacitively coupled plasma processing apparatus capable of easily and freely controlling plasma density distribution by using a movable mechanism for preventing particles from being adhered to a substrate to be processed, thereby improving production yield and/or uniformity of plasma processing.

In accordance with an aspect of the present invention, there is provided a plasma processing apparatus including a vacuum evacuable processing chamber; a first electrode for mounting thereon a substrate to be processed in the processing chamber; a second electrode which faces the first electrode obliquely or in parallel thereto to form a high frequency discharging capacitor; a processing gas supply unit for supplying a processing gas to a processing space formed above the substrate and a peripheral portion thereof in the processing chamber; and a first high frequency power supply for applying a first high frequency power to at least one of the first and the second electrode to generate a plasma by injecting the processing gas into the processing space.

The apparatus further includes an electrode position varying mechanism for varying a position of the second electrode in a predetermined direction to vary a capacitance of the capacitor; and a dielectric partition wall for separating the processing space from an electrode moving space surrounding the second electrode and the electrode position varying mechanism.

In the capacitively coupled plasma processing apparatus, the high frequency discharging capacitor is formed between the first electrode and the second electrode and, also, the high frequency discharging capacitor is formed between the first electrode and the sidewall of the processing chamber. Here, the dielectric partition wall only increases the capacity of the capacitor electrically between the first electrode and the second electrode by a predetermined amount. The dielectric partition wall does not particularly affect the high frequency discharge characteristics or the high frequency electric field characteristics between the electrodes.

When the capacity of the capacitor between the first electrode and the second electrode is increased by shifting the position of the second electrode in the predetermined direction by the electrode position varying mechanism, the high frequency current flowing between the electrodes increases and, also, the plasma density in that region, especially near the electrode central portion, increases. Meanwhile, the high frequency current flowing between the first electrode and the sidewall of the chamber decreases by the increased amount of the high frequency current between the first electrode and the second electrode, and the plasma density in that region, especially near the electrode central portion, increases. However, when the capacity of the capacitor between the first electrode and the second electrode is decreased by shifting the position of the second electrode in the reverse direction, the opposite operations are performed. Accordingly, the plasma density near the electrode central portion decreases, whereas the plasma density near the electrode edge portion increases. That is, the plasma density distribution on the substrate mounted on the first electrode can be easily and freely controlled by varying the position of the second electrode by the electrode position varying mechanism.

Moreover, in the above-described configuration, the electrode moving space surrounding the movable second electrode and the electrode position varying mechanism is separated from the vacuum processing space by the dielectric partition wall. Therefore, the particles generated in the electrode moving space are prevented from being adhered to the substrate in the processing space. The electrode position varying mechanism may not have a vacuum structure.

In accordance with an embodiment of the present invention, the dielectric partition wall may be provided horizontally at an upper portion of the first electrode in the processing chamber. The first and the second electrode may face each other in parallel, and be horizontally arranged above and below the dielectric partition wall, respectively. Further, the electrode moving mechanism may vary the position of the second electrode in a vertical direction.

The dielectric partition wall may be provided with a gas jetting unit for jetting the processing gas toward the processing space.

In this parallel plate type electrode structure, if the second electrode is movable, the electrode position varying mechanism can be installed, with a simple configuration, on the rear side of the ceiling of the processing chamber. In addition, the second electrode is not directly exposed to the plasma and, thus, the life span of the corresponding electrode can be extended.

In accordance with another embodiment of the present invention, the first electrode may be provided horizontally in the processing chamber, and the dielectric partition wall preferably provided on a sidewall of the processing chamber. Further, the second electrode facing the first electrode obliquely is disposed outside the dielectric partition wall. In this case, the electrode position varying mechanism may vary the position of the second electrode in a vertical direction or radial direction.

Further, a third electrode may be provided directly above the first electrode to face the first electrode in parallel while being provided independently of the second electrode to form a high frequency discharging capacitor with the first electrode.

In accordance with another aspect of the present invention, there is provided a plasma processing apparatus including a vacuum evacuable processing chamber; a first electrode and a second electrode for forming a high frequency capacitor horizontally provided at a lower portion and an upper portion of the processing chamber, respectively; an electrode position varying mechanism for varying a position of the first electrode in a vertical direction to vary a capacitance of the capacitor; and a dielectric partition wall mounting thereon a substrate to be processed between the first electrode and the second electrode in the processing chamber and separating the processing space formed above the substrate and a peripheral portion thereof from an electrode moving space surrounding the second electrode and the electrode position varying mechanism.

The apparatus further includes a processing gas supply unit for supplying a processing gas into the processing space; and a first high frequency power supply for applying a first high frequency power to at least one of the first and the second electrode to generate a plasma of the processing gas in the processing space.

In the above apparatus configuration, the position of the first electrode (lower electrode) is varied by the electrode position varying mechanism. Therefore, the plasma density distribution on the substrate mounted on the first electrode can be easily and freely controlled. Further, the electrode moving space surrounding the movable first electrode and the electrode position varying mechanism is separated from the vacuum processing space by the dielectric partition wall. Accordingly, the particles generated in the electrode moving space are prevented from being adhered to the substrate in the processing space. For that reason, the electrode position varying mechanism does not need a vacuum structure.

In accordance with the capacitively coupled plasma processing apparatus of the present invention, due to the above-described configuration and operation, the plasma density distribution can be easily and freely controlled by the movable mechanism for preventing particles from being adhered to a substrate to be processed and, also, the plasma processing uniformity or the production yield can be improved.

### BRIEF DESCRIPTION OF THE DRAWINGS

The above and other objects and features of the present invention will become apparent from the following description of embodiments, given in conjunction with the accompanying drawings, in which:

FIG. 1 is a vertical cross sectional view showing a configuration of a plasma processing apparatus in accordance with a first embodiment of the present invention;

FIG. 2A schematically describes an operation performed by lowering a position of an upper electrode in the plasma processing apparatus in accordance with the first embodiment of the present invention;

FIG. 2B schematically illustrates an operation performed by raising the position of the upper electrode in the plasma processing apparatus in accordance with the first embodiment of the present invention;

FIG. 3 provides a vertical cross sectional view showing a configuration of a plasma processing apparatus in accordance with a second embodiment of the present invention;

FIG. 4 presents a vertical cross sectional view showing a configuration of a plasma processing apparatus in accordance with a third embodiment of the present invention;

FIG. 5 represent a vertical cross sectional view showing a configuration of a plasma processing apparatus in accordance with a fourth embodiment of the present invention;

FIG. 6 is a vertical cross sectional view showing a configuration of a plasma processing apparatus in accordance with a fifth embodiment of the present invention; and

FIG. 7 offers an approximate top view depicting an arrangement configuration of an electrode position varying mechanism and a side electrode in the plasma processing apparatus in FIG. 6.

### DETAILED DESCRIPTION OF THE EMBODIMENT

The embodiments of the present invention will be described with reference to the accompanying drawings which form a part hereof.

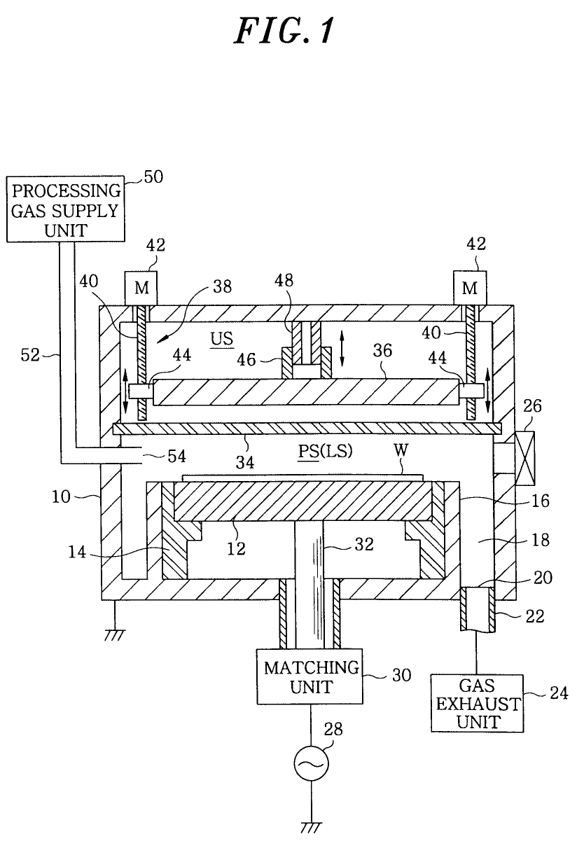

FIG. 1 shows a configuration of a plasma etching apparatus in accordance with a first embodiment of the present invention. The plasma etching apparatus is configured as a capacitively coupled plasma etching apparatus of cathode coupled type having parallel plate electrodes, and includes a cylindrical chamber (processing vessel) 10 made of a metal such as aluminum, stainless steel or the like. The chamber 10 is frame grounded.

A circular plate-shaped susceptor 12 serving as a lower electrode for mounting thereon a substrate to be processed, e.g., a semiconductor wafer W, is disposed horizontally in the chamber 10. The susceptor 12 is made of, e.g., aluminum, and is supported by a cylindrical insulating supporting portion 14 which is made of ceramic and vertically extends from a bottom of the chamber 10 without being grounded. An annular gas exhaust path 18 is formed between the inner wall of the chamber 10 and a cylindrical conductive supporting portion 16 vertically extending from the bottom of the chamber 10 along the periphery of the cylindrical supporting portion 14. A gas exhaust port 20 is provided at the bottom portion of the gas exhaust path 18, and a gas exhaust unit 24 is connected to the gas exhaust port 20 via a gas exhaust line 22. The gas exhaust unit 24 has a vacuum pump such as a turbo molecular pump or the like, so that a processing space in the chamber 10 can be depressurized to a desired vacuum level. Provided on the sidewall of the chamber 10 is a gate valve 26 for opening and closing a loading/unloading port of the semiconductor wafer W.

A high frequency power supply 28 for plasma and DC bias generation is electrically connected to the susceptor 12 via a matching unit 30 and a power feed rod 32. The high frequency power supply 28 outputs a predetermined high frequency power of, e.g., a high frequency of about 40 MHz, at a desired power. The matching unit 30 matches an impedance between the high frequency power supply 28 and a load (mainly, an electrode, a plasma and a chamber).

Although it is not illustrated, the susceptor 12 may have therein a coolant reservoir or a coolant path where a coolant flows for temperature control. Further, in order to increase wafer temperature accuracy, there may be provided a gas channel for supplying a thermally conductive gas, e.g., He gas, from a thermally conductive gas supply unit to the top surface of the susceptor 12 (the backside of the semiconductor wafer W). In that case, an electrostatic chuck for adsorbing a wafer is provided on the top surface of the susceptor 12.

At an upper portion of the susceptor 12, a circular plate-shaped partition plate 34 made of dielectric, e.g., quartz, is horizontally provided at a predetermined position to face the susceptor 12, and a circular plate-shaped upper electrode 36 is horizontally disposed above the quartz partition plate 34.

The upper electrode 36 is made of, e.g., aluminum, and can be moved or displaced in a vertical direction by an electrode position varying mechanism 38 installed on a top surface wall of the chamber 10. The illustrated electrode position varying mechanism 38 is formed as, e.g., a ball screw mechanism, and includes a step motor 42 coupled to an upper portion of a screw axis 40 extending in a vertical direction and a driving nut portion 44 connected to the upper electrode 36 to form one body and screw-coupled to the screw axis 40. By controlling the rotation direction and the rotation amount of the step motor 42, the moving direction (upward/downward) and the moving amount of the upper electrode 36 can be controlled. Also, the height position of the upper electrode 36 and the distance between the upper electrode 36 and the susceptor 12 can be continuously varied within a predetermined range. Further, the driving nut portion 44 and the upper electrode 36 are preferably electrically insulated.

A cylindrical conductor 46 having a relatively large diameter which extends vertically upward from the rear central portion of the upper electrode 36 is fitted to a cylindrical conductor 48 to slidably move therealong, the cylindrical conductor 48 having a relatively small diameter which extends vertically downward from the upper wall of the chamber 10. The upper electrode 36 is grounded via the cylindrical conductors 46 and 48 and the chamber 10 at any vertical position.

The quartz partition plate 34 divides the space in the chamber 10 into an upper space US and a lower space LS. The upper space US is a space surrounding the upper electrode 36 and the electrode position varying mechanism 38 in which the upper electrode can move around, and may communicate with the atmosphere. Meanwhile, the lower space LS is sealed by a sealing member (not shown) so that it can be depressurized. Especially, a processing space PS or a plasma generating space of vacuum is formed between the susceptor 12 and the quartz partition plate 34.

In the embodiment of the present invention, a gas supply line 52 extending from a processing gas supply unit 50 passes a sidewall of the chamber 10 to communicate with the processing space PS through a gas injection opening 54 provided in the sidewall of the chamber 10 to supply a processing gas thereto).

A control unit (not shown) formed of, e.g., a micro computer, controls an operation (sequence) of the entire apparatus and an operation of each unit in the plasma etching apparatus such as the gas exhaust unit 24, the high frequency power supply 28, the electrode position varying mechanism 38, the processing gas supply unit 50 and the like.

To carry out an etching in the plasma etching apparatus, first of all, the gate valve 26 is opened. Next, the semiconductor wafer W serving as a target object to be processed is loaded into the chamber 10 and then is mounted on the susceptor 12. Thereafter, an etching gas (generally a gaseous mixture) from the processing gas supply unit 50 is introduced into the sealed processing space PS of the chamber 10 at a predetermined flow rate, and the pressure in the processing space PS of the chamber 10 is maintained to be a set value by the gas exhaust unit 24. Moreover, the high frequency power supply 28 is turned on, so that the high frequency power (40 MHz) is outputted at a predetermined power level and supplied to the susceptor (lower electrode) 12 via the matching unit 30 and the power feed rod 32. In the processing space PS on the susceptor 12, the etching gas discharged through the gas discharge openings 54 is converted into a plasma by the high frequency discharge between the susceptor 12 and the upper electrode 36 and between the susceptor 12 and the sidewall of the chamber 10. Next, the main surface of the semiconductor wafer W is etched in a predetermined pattern by radicals or ions generated in the plasma.

In the capacitively coupled plasma etching apparatus, by applying the high frequency power greater than or equal to about 40 MHz to the susceptor 12, a high-density plasma in a desirable dissociation state can be generated even at a relatively low pressure level. Further, in the capacitively coupled plasma etching apparatus, the anisotropic etching can be carried out by attracting ions in the plasma to the wafer W in a substantially vertical direction by using a self-bias voltage generated on the susceptor 12.

This capacitively coupled plasma etching apparatus is characterized by the configuration in which the susceptor (lower electrode) 12 is fixed in a predetermined position and the upper electrode 36 is movable in a vertical direction (in a distance direction between electrodes), the susceptor 12 and the upper electrode 36 forming a pair of high frequency discharging parallel plate electrodes, and in which an electrode moving space US surrounding the upper electrode 36 and the electrode position varying mechanism 38 is isolated atmospherically from the processing space PS formed above the semiconductor wafer W and in a peripheral portion thereof on the susceptor 12 by the quartz partition plate 34.

The quartz partition plate 34 electrically increases the capacitance of the capacitor formed between the susceptor 12 and the upper electrode 36 by a specific amount in accordance with a dielectric constant and a thickness thereof. The RF current between the susceptor 12 and the upper electrode 36 as well as the RF current between the susceptor 12 and the sidewall of the chamber 10 are not particularly affected by the presence of the quartz partition plate 34.

By varying the position of the upper electrode 36 in a vertical direction (in a distance direction between the electrodes), the balance between the high frequency discharge between the susceptor 12 and the upper electrode 36 and that between the susceptor 12 and the sidewall of the chamber 10 can be variably controlled under the condition that the high frequency power applied from the high frequency power supply 28 to the susceptor 12 is maintained at a specific frequency.

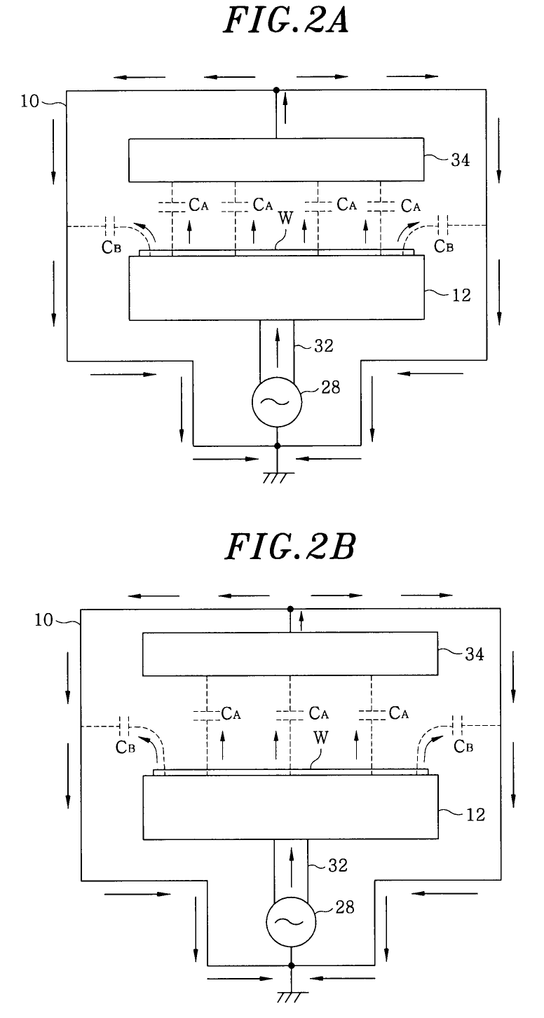

FIGS. 2A and 2B schematically illustrate the operation performed by vertically varying the position of the upper electrode 36 in the plasma processing apparatus in FIG. 1. In the cathode coupled plasma processing apparatus, the sidewall of the chamber 10 as well as the upper electrode 36 serve as an anode of a ground potential with respect to the susceptor 12 serving as a cathode. Accordingly, a capacitor C_{A} is formed between the susceptor 12 and the upper electrode 36 and, also, a capacitor C_{B} is formed between the susceptor 12 and the sidewall of the chamber 10.

When the high frequency power is applied from the high frequency power supply 28 to the susceptor 12, a plasma of a processing gas is generated in the processing space PS by a high frequency discharge between the susceptor 12 and the upper electrode 36 and that between the susceptor 12 and the sidewall of the chamber 10. The plasma thus generated is diffused in every direction. A part of the RF current in the plasma reaches the upper electrode 36 via the quartz partition plate 34 (see FIG. 1), and then returns to the high frequency power supply 28 via the sidewall of the chamber 10 and the ground line. The rest of the RF current reaches the sidewall of the chamber 10 directly, and then returns to the high frequency power supply 28 via the ground line.

Here, when the distance between the electrodes 12 and 36 is reduced by lowering the position of the upper electrode 36 as shown in FIG. 2A, the intensity of the RF electric field and the capacitance of the capacitor C_{A} increase between the electrodes 12 and 36, and the RF current passing through the capacitor C_{A} increases. Meanwhile, the distance between the susceptor 12 and the sidewall of the chamber 10 is not changed, and, thus the capacitance of the capacitor C_{B} is uniformly maintained. Accordingly, the RF current passing through the capacitor C_{B} decreases by the increased amount of the RF current passing through the capacitor C_{A}. This increases the ratio of the RF current flowing toward the upper electrode 36 and decreases the ratio of the RF current flowing toward the sidewall of the chamber 10 among the RF currents flowing from the plasma to the anodes. In addition, due to the skin effect in which the RF current is easily concentrated on the central portion of the main surface of the susceptor 12, the plasma density distribution on the semiconductor wafer W shows a profile that is relatively higher at the wafer central portion and relatively low at the edge portion.

On the contrary, when the distance between the electrodes 12 and 36 is increased by raising the position of the upper electrode 36 as illustrated in FIG. 2B, the intensity of the RF electric field and the capacitance of the capacitor C_{A} decrease between electrodes 12 and 36, and the RF current passing through the capacitor C_{A} decreases. Meanwhile, the distance between the susceptor 12 and the sidewall of the chamber 10 is not changed, and, thus the capacitance of the capacitor C_{B} is uniformly maintained. Accordingly, the RF current passing through the capacitor C_{B} is increased by the decreased amount of the RF current passing through the capacitor C_{A}. This increases the ratio of the RF current flowing toward the sidewall of the chamber 10 and decreases the ratio of the RF current flowing toward the upper electrode 36 among the RF currents flowing from the plasma to the anodes. As a result, the plasma density distribution on the semiconductor wafer W can be corrected by increasing the plasma density at the edge portion and decreasing the plasma density at the wafer central portion.

As described above, the plasma density distribution on the semiconductor wafer W can be easily and freely controlled in a radial direction by varying the position of the upper electrode 36 with the use of the electrode position varying mechanism 38. Thus, the plasma etching characteristics (especially, intra-wafer uniformity) can be improved.

Moreover, as shown in FIG. 1, the electrode moving space US is physically separated from the processing space PS by the quartz partition plate 34. Therefore, even if particles are generated by friction caused by moving or displacing the electrode position varying mechanism 38 or the upper electrode 36 in the electrode moving space US, the particles do not reach the processing space PS formed under the quartz partition plate 34. Hence, the particles are not adhered to the semiconductor wafer W on the susceptor 12. This is very advantageous in view of a quality management and a manufacturing yield.

Moreover, the upper electrode 36 is separated by the quartz partition wall 34 from the processing space PS, so that an etching by-product such as polymer or the like is not deposited on the surface of the upper electrode 36 and, also, ion incidence does not take place. Accordingly, the life span of the electrode can be prolonged without performing a special surface treatment such as an alumite process or the like on the upper electrode 36.

Furthermore, the electrode position varying mechanism 38 operates in a non-vacuum electrode moving space US communicating with the atmosphere, so that it can be realized with a simple structure and at a low cost.

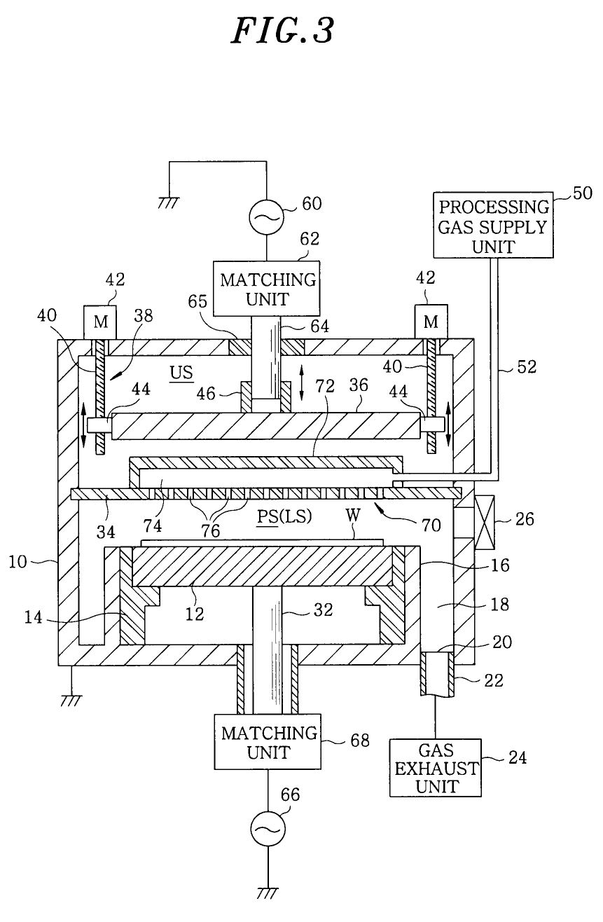

FIG. 3 shows a configuration of a plasma processing apparatus in accordance with a second embodiment of the present invention. The configuration and the operation of this plasma processing apparatus are substantially the same as those of the plasma processing apparatus of the first embodiment except that two high frequencies are used and that a shower head is provided to supply a processing gas into the processing space PS.

To be more specific, a first high frequency power of a relatively high frequency (e.g., about 60 MHz) suitable for plasma generation is applied from a high frequency power supply 60 to the upper electrode 36 via a matching unit 62 and an upper power feed rod 64. Meanwhile, a second high frequency power of a relatively low frequency (e.g., about 2 MHz) suitable for ion attraction from a plasma to a semiconductor wafer W is applied from a second high frequency power supply 66 to the susceptor (lower electrode) 12 via a matching unit 68 and a lower power feed rod 32. In this dual frequency application type, the plasma density and the ion energy can be independently controlled by selecting the first and the second high frequency power independently, so that a degree of freedom or controllability of the etching processing can be improved.

Further, a cylindrical conductor 46 disposed on the rear surface of the upper electrode 36 is fitted to the upper power feed rod 64 to be slidably move therealong. The upper power feed rod 64 is supported on the top surface of the chamber 10 by an insulator 65.

A shower head 70 is configured by using the quartz partition wall 34. That is, a buffer chamber 74 having a quartz plate wall 72 made of, e.g., dielectric, is formed at a rear side of the quartz plate 34. A gas supply line 52 extending from a processing gas supply unit 50 is connected to the buffer chamber 74. A plurality of gas injection openings 76 are formed in the quartz partition plate 34. During the etching process, an etching gas from the processing gas supply unit 50 is introduced into the buffer chamber 74 via the gas supply line 52, and then is introduced into the processing space PS through the gas injecting openings 76. The quartz partition plate 34 and quartz plate wall 72 forming the shower head 70 are all made of dielectric, and do not particularly affect the RF electric field characteristics between the upper electrode 36 and the susceptor 12 and the high frequency discharge characteristics in the processing space PS.

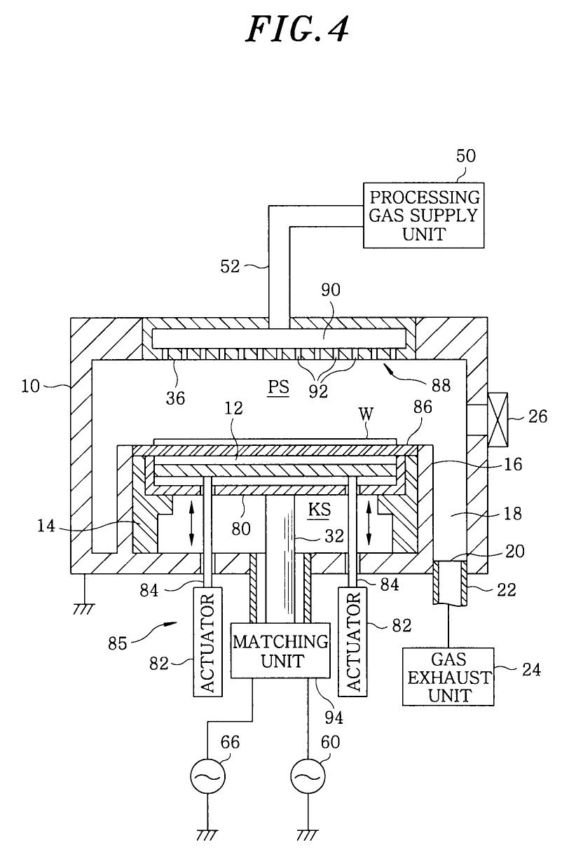

FIG. 4 illustrates a configuration of a plasma processing apparatus in accordance with a third embodiment of the present invention. This plasma processing apparatus is characterized by a configuration in which the upper electrode 36 is fixed at a specific position, and a position of the lower electrode 12 is vertically varied. Specifically, a circular plate-shaped lower electrode 12 is vertically movable in a cylindrical conductor cup 80 having a bottom portion which is coupled to the lower power feed rod 32, and a height position of the lower electrode 12 is varied by actuators 82 installed outside the chamber 10 via supporting rods 84. Here, the conductor cup 80 and the lower electrode 12 may be electrically connected to each other directly or via a flexible conductor (not shown). The supporting rods 84 may be formed of an insulator, and the actuators 82 may be formed as ball screw mechanisms, a cylinder or the like.

The top surface of the conductor cup 80 is airtightly sealed by a partition plate 86 made of dielectric, e.g., quartz. The semiconductor wafer W to be processed is mounted on the quartz plate 86. Although it is not illustrated, the quartz partition plate 86 may be provided as a unit with an electrostatic chuck.

The electrode moving space KS around the lower electrode 12 and the electrode position varying mechanism 85 (the actuators 82 and the supporting rods 84) is separated atmospherically, by the quartz partition plate 86, from the processing space PS formed on the semiconductor wafer W to be processed and a peripheral portion thereof. The electrode moving space KS communicates with the atmosphere. Meanwhile, the processing space PS is sealed to be depressurized by a sealing member (not shown).

The upper electrode 36 is grounded by being built in the chamber 10 as a unit therewith, and serves also as a shower head 88. The processing gas supplied from the processing gas supply unit 50 is introduced into a gas buffer chamber 90 in the upper electrode 36 via the gas supply line 52, and then is uniformly injected from the gas buffer chamber 90 to the processing space PS through gas injection openings 92 of the upper electrode 36.

This plasma etching apparatus employs a cathode coupled lower electrode dual frequency application type. Here, the first high frequency power supply 60 for plasma generation as well as the second high frequency power supply 66 for ion attraction are electrically connected to the lower electrode 12 via the matching unit 94, the lower power feed rod 32 and the conductor cup 80. The matching unit 94 includes a matching unit for the first high frequency power supply 60 and that for the second high frequency power supply 66.

In the present embodiment as well, high frequency discharging capacitors are formed between the lower electrode 12 and the upper electrode 36 and between the lower electrode 12 and the sidewall of the chamber 10. During the etching process, an etching gas is supplied through the shower head 88 to the processing space PS at a predetermined pressure and, at the same time, the first and the second high frequency are applied from the high frequency power supplies 60 and 66 to the susceptor 12. A plasma of the processing gas is generated in the processing space PS by a high frequency discharge between the susceptor 12 and the upper electrode 36 and that between the susceptor 12 and the sidewall of the chamber 10. Next, the main surface of the semiconductor wafer W is etched in a predetermined pattern by radicals or ions generated by the plasma.

In this plasma etching apparatus, as described with reference to FIGS. 2A and 2B, the plasma density distribution on the semiconductor wafer W can be easily and freely controlled in a radial direction by vertically varying the position of the lower electrode 12 with the use of the electrode position varying mechanism 85. Accordingly, the etching characteristics (especially, uniformity) can be improved. Further, as depicted in FIG. 4, the electrode moving space KS is physically separated from the processing space PS by the quartz partition plate 86. Therefore, even if particles are generated from the electrode position varying mechanism 85 or the lower electrode 12 in the electrode moving space KS, the particles do not reach the processing space PS and thus are not adhered to the semiconductor wafer W on the susceptor 12. The electrode position varying mechanism 85 is provided and operates in the electrode moving space KS of an atmospheric pressure, so that it can be realized with a simple structure and at a low cost.

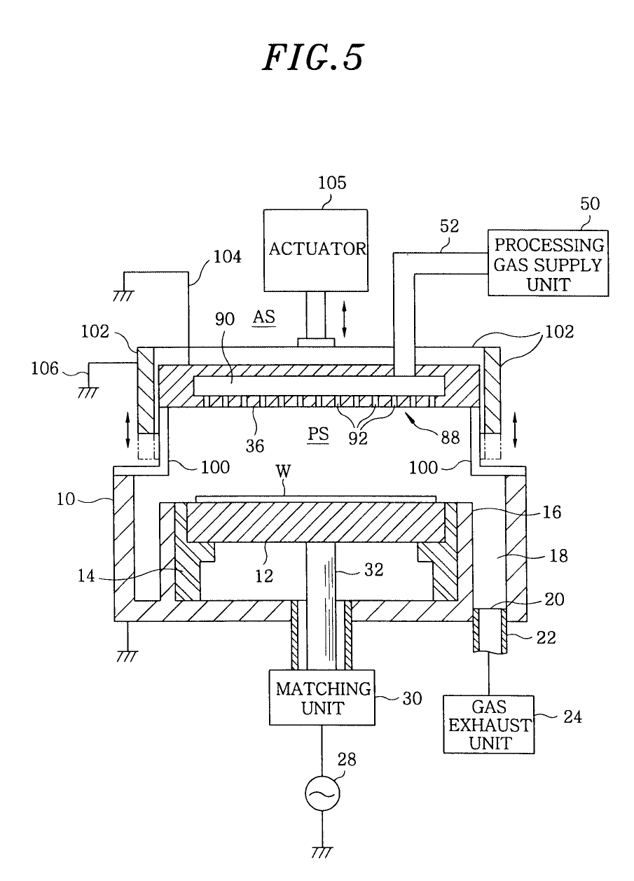

FIG. 5 describes a configuration of a plasma processing apparatus in accordance with a fourth embodiment of the present invention. In this plasma processing apparatus, the susceptor (lower electrode) 12 and the upper electrode 36 facing each other in parallel are horizontally fixed at specific positions, and a cylindrical sidewall portion 100 made of, e.g., quartz, is provided on the sidewall of the chamber 10 facing the processing space PS formed between electrodes 12 and 36. Further, in addition to the quartz sidewall portion 100, a cylindrical side electrode 102 is disposed outside of the sidewall portion 100 to be movable or displaceable in a vertical direction.

To be more specific, a cathode coupled single frequency application type is employed in this plasma processing apparatus, so that the configuration around the susceptor (lower electrode) 12 may be the same as that described in the first embodiment (see FIG. 1). Meanwhile, the upper electrode 36 serves as the shower head 88 as well as an anode, and is grounded via a ground line 104. The side electrode 102 serves as an anode separate from the upper electrode 36, and is grounded via an individual ground line 106. An electrode position varying mechanism 105 includes an actuator, e.g., a ball screw mechanism, a cylinder or the like. Due to the presence of the electrode position varying mechanism 105, the side electrode 102 can move vertically along the quartz sidewall portion 100 within a predetermined range, and also can be supported at an arbitrary vertical position.

The upper electrode 36 faces the susceptor (lower electrode) 12 in parallel to each other via the processing space PS, and a parallel plate type capacitor is formed between the electrodes 36 and 12. Meanwhile, the side electrode 102 faces the susceptor 12 obliquely via the quartz sidewall portion 100 and the processing space PS, and a non-parallel plate type capacitor is formed between the electrodes 102 and 12.

When the high frequency power is applied from the high frequency power supply 28 to the susceptor 12, a plasma of a processing gas is generated in the processing space PS by a high frequency discharge between the susceptor 12 and the upper electrode 36 and that between the susceptor 12 and the side electrode 102. The plasma thus generated is diffused in every direction. A part of the RF current in the plasma reaches the upper electrode 36, and returns to the high frequency power supply 28 via the ground line 104. The rest of the RF current reaches the side electrode 102 via the quartz wall portion 100, and returns to the high frequency supply 28 via the ground line 106.

Here, when the position of the side electrode 102 is lowered by the actuator (the electrode position varying mechanism 105), an effective area where the side electrode 102 and the susceptor 12 face each other increases. In other words, the area (capacitance) of the capacitor between the electrodes 12 and 102 increases. Accordingly, among the RF currents flowing from the plasma to the anodes, the ratio of the RF current flowing toward the side electrode 102 increases, whereas the ratio of the RF current flowing toward the upper electrode 36 decreases. That is, the plasma density distribution characteristics can be controlled to decrease the plasma density at the wafer central portion and increase the plasma density at the edge portion on the semiconductor wafer W to be processed.

On the contrary, when the position of the side electrode 102 is raised by the actuator (electrode position varying mechanism 105), an effective area where the side electrode 102 and the susceptor 12 face each other decreases. In other words, the area (capacitance) of the capacitor between the electrodes 12 and 102 decreases. Accordingly, among the RF currents flowing from the plasma to the anodes, the ratio of the RF current flowing toward the side electrode 102 decreases, whereas the ratio of the RF current flowing toward the upper electrode 36 increases. That is, the plasma density distribution characteristics can be controlled to increase the plasma density at the wafer central portion and decrease the plasma density at the edge portion on the semiconductor wafer W to be processed.

In the present embodiment, the plasma density distribution on the semiconductor wafer W can be easily and freely controlled in a radial direction by vertically varying the position of the side electrode 102 with the use of the electrode position varying mechanism 105. Moreover, as illustrated in FIG. 5, the quartz sidewall portion 100 of the chamber 10 physically separates the electrode moving space (atmospheric space) AS around the side electrode 102 and the electrode position varying mechanism 105 from the processing space PS of the chamber 10. Therefore, even if particles are generated from the electrode position varying mechanism 105 or the side electrode 102, the particles are not transferred from the electrode moving space AS to the processing space PS and thus are not adhered to the semiconductor wafer W on the susceptor 12. Further, the electrode position varying mechanism 105 is provided and operates in the electrode moving space KS of an atmospheric pressure, so that it can be realized with a simple structure and at a low cost.

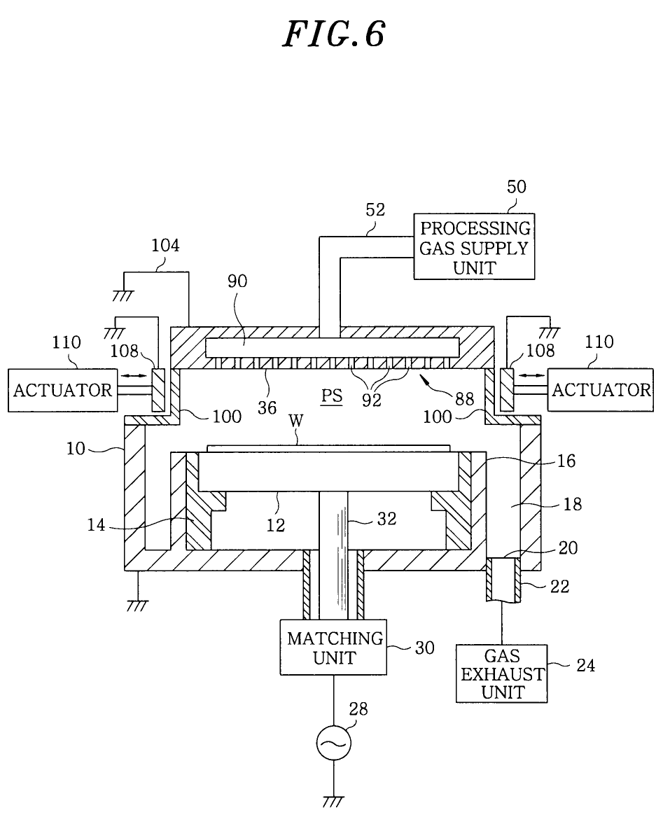

FIG. 6 shows a configuration of a plasma processing apparatus in accordance with a fifth embodiment of the present invention. This embodiment is a modification of the fourth embodiment. Here, side electrodes 108 are disposed outside the quartz member portion 100 to be movable or displaceable in a horizontal radial direction.

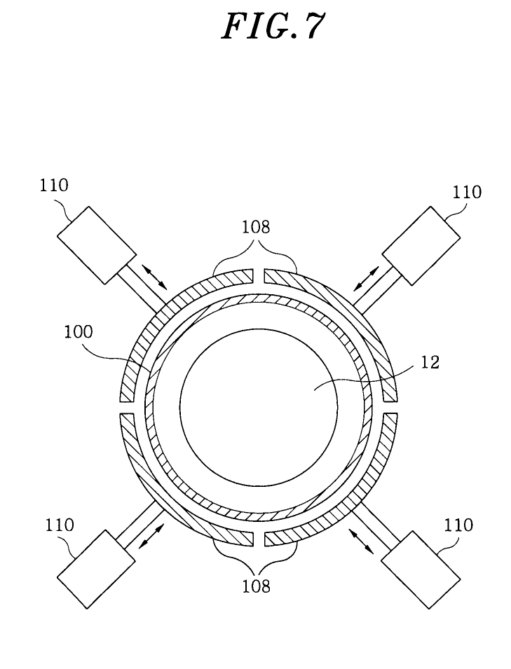

In order to move and displace the side electrodes 108 in a radial direction, the side electrode 108 is provided with a plurality of, e.g., four, arc-shaped members which are divided in a circumferential direction, as illustrated in FIG. 7. Each member has a linearly moving actuator 110 along radial direction as an electrode position varying mechanism.

When the position of the side electrode 108 is shifted toward an inner side of a radial direction by the actuators (electrode position varying mechanism) 110, the distance between the side electrode 108 and the susceptor 12 decreases. That is, an area (capacitance) of the capacitor between the electrodes 12 and 108 increases. Further, among the RF currents flowing from the plasma to the anodes, the ratio of the RF current flowing toward the side electrode 108 increases, whereas the ratio of the RF current flowing toward the upper electrode 36 decreases by that amount. Therefore, the plasma density distribution characteristics can be controlled to decrease the plasma density at the wafer central portion and increase the plasma density at the edge portion.

On the contrary, when the position of the side electrode 108 is shifted toward an outer side of a radial direction by the actuators 110, the distance between the side electrode 108 and the susceptor 12 increases. That is, an area (capacitance) of the capacitor between the electrodes 12 and 108 increases. Further, among the RF currents flowing from the plasma to the anodes, the ratio of the RF current flowing toward the side electrode 108 decreases, whereas the ratio of the RF current flowing toward the upper electrode 36 increases by that amount. Therefore, the plasma density distribution characteristics can be controlled to increase the plasma density at the wafer central portion and decrease the plasma density at the edge portion.

In this embodiment, although the moving or displacing direction of the side electrode 108 is different from that of the side electrode 102 in the fourth embodiment, same operation effects as in the fourth embodiment can be obtained.

Further, although it is not illustrated, the fourth or the fifth embodiment may have a configuration in which a dielectric partition plate is provided between the upper electrode 36 and the susceptor 12 and the position of the upper electrode 36 is vertically varied separately from the side electrode 102 (108).

In a conventional etching process, when a single treatment is performed on a single semiconductor wafer, a plurality of steps (e.g., etching a mask of a surface, vertically cutting an insulating film under the mask, applying an over-etching by increasing selectivity to a base layer and the like) are often carried out successively while changing the processing conditions such as a pressure, power, gas and the like. In accordance with the present embodiments, the electrode position varying mechanism can function so that the plasma distribution characteristics can be optimized in each of the steps.

The present invention can be variously modified without being limited to the aforementioned embodiments of the present invention. Especially, the configuration of the electrode position varying mechanism and the movable electrode can be variously selected and modified to be optimally combined with other mechanisms in the apparatus.

The present invention is not limited to the plasma etching apparatus, and can also be applied to other plasma processing apparatuses for performing plasma CVD, plasma oxidation, plasma nitriding, sputtering and the like. Further, as for a substrate to be processed of the present invention, it is possible to use various substrates for flat panel display, a photomask, a CD substrate, a printed circuit board and the like, other than a semiconductor wafer.

While the invention has been shown and described with respect to the embodiments, it will be understood by those skilled in the art that various changes and modification may be made without departing from the scope of the invention as defined in the following claims.

What is claimed is:

1. A plasma processing apparatus comprising:
a vacuum evacuable processing chamber;
a first electrode for mounting thereon a substrate to be processed in the processing chamber;
a second electrode which faces the first electrode obliquely or in parallel thereto to form a high frequency discharging capacitor;
a processing gas supply unit for supplying a processing gas to a processing space formed above the substrate and a peripheral portion thereof in the processing chamber;
a first high frequency power supply for applying a first high frequency power to at least one of the first and the second electrode to generate a plasma by injecting the processing gas into the processing space;
an electrode position varying mechanism for varying a position of the second electrode in a predetermined direction to vary a capacitance of the capacitor; and
a dielectric partition wall for separating the processing space from an electrode moving space surrounding the second electrode and the electrode position varying mechanism.

2. The plasma processing apparatus of claim 1, wherein the dielectric partition wall is provided horizontally at an upper portion of the first electrode in the processing chamber; the first and the second electrode face each other in parallel, and are horizontally arranged above and below the dielectric partition wall, respectively; and the electrode moving mechanism varies the position of the second electrode in a vertical direction.

3. The plasma processing apparatus of claim 2, wherein the dielectric partition wall is provided with a gas jetting unit for jetting the processing gas toward the processing space.

4. The plasma processing apparatus of claim 1, wherein the first electrode is provided horizontally in the processing chamber; the dielectric partition wall is provided on a sidewall of the processing chamber; and the second electrode facing the first electrode obliquely is disposed outside the dielectric partition wall.

5. The plasma processing apparatus of claim 4, wherein the electrode position varying mechanism varies the position of the second electrode in a vertical direction.

6. The plasma processing apparatus of claim 4, wherein the electrode position varying mechanism varies the position of the second electrode in a radial direction.

7. The plasma processing apparatus of claim 5, further comprising a third electrode provided directly above the first electrode to face the first electrode in parallel while being provided independently of the second electrode to form a high frequency discharging capacitor with the first electrode.

8. The plasma processing apparatus of claim 6, further comprising a third electrode provided directly above the first electrode to face the first electrode in parallel while being provided independently of the second electrode to form a high frequency discharging capacitor with the first electrode.

9. A plasma processing apparatus comprising:
a vacuum evacuable processing chamber;
a first electrode and a second electrode for forming a high frequency capacitor horizontally provided at a lower portion and an upper portion of the processing chamber, respectively;
an electrode position varying mechanism for varying a position of the first electrode in a vertical direction to vary a capacitance of the capacitor;
a dielectric partition wall mounting thereon a substrate to be processed between the first electrode and the second electrode in the processing chamber and separating the processing space formed above the substrate and a peripheral portion thereof from an electrode moving space surrounding the second electrode and the electrode position varying mechanism;
a processing gas supply unit for supplying a processing gas into the processing space; and
a first high frequency power supply for applying a first high frequency power to at least one of the first and the second electrode to generate a plasma of the processing gas in the processing space.

10. The plasma processing apparatus of claim 1, wherein the electrode position varying mechanism has a unit for moving the second electrode to an arbitrary position within a predetermined range and supporting the movable electrode at the position.

11. The plasma processing apparatus of claim 9, wherein the electrode position varying mechanism has a unit for moving the first electrode to an arbitrary position within a predetermined range and supporting the movable electrode at the position.

12. The plasma processing apparatus of claim 1, wherein the electrode moving space communicates with the atmosphere.

13. The plasma processing apparatus of claim 9, wherein the electrode moving space communicates with the atmosphere.

14. The plasma processing apparatus of claim 1, further comprising a second high frequency power supply for applying to the first electrode a second high frequency power for ion attraction from the plasma to the substrate.

15. The plasma processing apparatus of claim 9, further comprising a second high frequency power supply for applying to the first electrode a second high frequency power for ion attraction from the plasma to the substrate.
